(19) United States
(12) Patent Application Publication
(10) Pub. No.: US 2025/0296833 A1
(43) Pub. Date: Sep. 25, 2025

(54) MICROSCANNER HAVING A DEFLECTING ELEMENT AND HAVING SPRING ELEMENTS CURVED TOWARDS SAME FOR SUSPENSION OF THE DEFLECTING ELEMENT IN A MANNER CAPABLE OF OSCILLATION

(71) Applicant: OQMENTED GMBH, Itzehoe (DE)

(72) Inventor: Fabian SCHWARZ, Itzehoe (DE)

(21) Appl. No.: 18/862,857

(22) PCT Filed: Apr. 25, 2023
(86) PCT No.: PCT/EP2023/060832

§ 371 Date: Nov. 4, 2024

(30) Foreign Application Priority Data
May 5, 2022 (DE) 10 2022 111 185.7

(51) Int. Cl. B81B 3/00; G02B 26/08; G02B 26/10

(52) U.S. Cl. CPC B81B 3/0045; G02B 26/0858; G02B 26/101; B81B 2201/042; B81B 2203/0154; B81B 2203/0163; B81B 2203/0307

(57) ABSTRACT

A microscanner for projecting electromagnetic radiation onto an observation field has: a deflection element having a mirror surface designed as a micromirror for deflecting an incident electromagnetic beam; a support structure that surrounds the deflection element at least in some sections; and (iii) a spring device, by means of which the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations. The spring device has a plurality of spring elements arranged together in a ring around the deflection element, which are each anchored, on the one hand, to a first anchoring point on the support structure and, on the other hand, are anchored directly or indirectly to a second anchoring point on the deflection element. In between, they each have an at least partially arced course such that this arced course is curved in the direction toward the deflection element.

The present invention relates to a microscanner for projecting electromagnetic radiation onto an observation field.

Microscanners, which are also referred to in the technical language in particular as “MEMS scanners”, “MEMS mirrors”, or “micromirrors”, or in English in particular as “micro-scanner” or “micro-scanning mirror” or “MEMS mirror”, are micro-electro-mechanical systems (MEMS) or more specifically micro-opto-electro-mechanical systems (MOEMS) from the class of micro-mirror actuators for dynamic modulation of electromagnetic radiation, in particular of visible light. Depending on the design, the modulating movement of an individual mirror can be translational or rotational around at least one axis. In the first case, a phase-shifting effect is achieved, and in the second case, the deflection of the incident electromagnetic radiation is achieved. We will also consider microscanners in which the modulating movement of an individual mirror is rotational. In microscanners, the modulation is generated via a single mirror, in contrast to mirror arrays, in which the modulation of incident light occurs via the interaction of multiple mirrors.

Microscanners may be used in particular to deflect electromagnetic radiation in order to modulate an electromagnetic beam incident thereon with respect to its direction by means of a deflection element (“mirror”). This can be used in particular to effectuate a Lissajous projection of the beam into an observation field or projection field. For example, imaging sensory objects can be achieved or display functionalities can be implemented. In addition, such microscanners can also be used to irradiate materials in an advantageous manner and thus also process them. Possible other applications are in the area of lighting or illuminating certain open or closed spaces or areas of space using electromagnetic radiation, for example in the context of headlight applications.

In many cases, microscanners consist of a mirror plate (deflection plate) that is suspended laterally on elastically stretchable springs. A distinction is made between single-axis mirrors, which are preferably only to be suspended to be movable around a single axis, and biaxial and multi-axis mirrors.

Both in the case of imaging sensors and in the case of a display function, a microscanner is used to deflect electromagnetic radiation such as a laser beam or a shaped beam from any other source of electromagnetic radiation at least two-dimensionally, for example horizontally and vertically, in order to thus scan or illuminate an object surface within an observation field. In particular, this can be done in such a way that the scanned laser beam sweeps over a rectangular area on a projection surface in the projection field. In these applications, microscanners having at least biaxial mirrors or single-axis mirrors connected in succession in the optical path are used. The wavelength range of the radiation to be deflected can in principle be selected from the entire spectrum from short-wave UV radiation, through the VIS range, NIR range, IR range, FIR range to long-wave terrestrial and radar radiation.

Microscanners are often manufactured using methods of semiconductor technology. Based on semiconductor wafer substrates, in particular silicon wafer substrates, layer deposition, photolithography, and etching techniques are used to form microstructures in the substrate and thus implement microscanners having movable MEMS mirrors, in particular as a chip. Other semiconductor materials are also possible instead of silicon.

In many known cases, microscanner-based laser projection displays are so-called raster scan displays, in which a first beam deflection axis is operated at high frequency in resonance (typically 15 kHz to 30 kHz) (fast axis) to generate the horizontal deflection and a second axis is operated quasi-statically at low frequency (typically 30 Hz to 60 Hz) to generate the vertical deflection. A fixed grid-like line pattern (trajectory) is typically reproduced 30 to 60 times per second.

A different approach is used in the so-called Lissajous microscanners, in particular also in Lissajous scan displays. There, both axes are usually operated in resonance and a scan path in the form of a Lissajous figure is created. In this way, large amplitudes can be achieved in both axes. The vertical deflection in particular can therefore be much larger than with a raster scanner. Accordingly, with a Lissajous microscanner, in particular a Lissajous scan display, a significantly higher optical resolution can usually be achieved than with a raster scan display, especially in the vertical direction.

A deflection device for a projection system for projecting Lissajous figures onto an observation field is known from EP 2 514 211 B1, which is designed to deflect a light beam around at least a first and a second deflection axis to generate the Lissajous figures.

Electrostatic, electromagnetic, piezoelectric, thermal, and other actuator principles are typically used to drive a microscanner, i.e., the oscillation of its deflection element or mirror. The mirror movement can in particular be quasi-static or resonant. The latter can be used in particular to achieve larger vibration amplitudes, larger deflections, and higher optical resolutions. In addition, in resonant operation, energy consumption can generally be minimized or advantages can be achieved, particularly in terms of stability, robustness, manufacturing yield, etc. Scanning frequencies from 0 Hz (quasi-static) to over 100 kHz (resonant) are typical.

However, various desirable properties of microscanners for biaxial resonant Lissajous operation are often difficult to reconcile. In particular, it is challenging to implement microscanners having mirror diameters between 0.5 mm and 30 mm, which, on the one hand, permit large optical scanning angles (for example in the range of at least 20° to 90°) to be achieved, and on the other hand, permit high scanning frequencies (for example between 2 kHz and 90 kHz) to be achieved and, for cost reasons, do not require more MEMS chip edge length than approximately twice or three times the mirror diameter.

High-performance MEMS mirror chips often have edge lengths that are 4-10 times larger than the mirror diameter, which is not only expensive to produce but can also severely restrict the possible applications, for example when it involves integration into a mobile consumer end product. The problem described increases in particular when not only a single-axis MEMS mirror, but a biaxial or multi-axis mirror is to be designed.

In order to achieve the large scanning angles despite the high required scanning frequencies, the MEMS designer is faced with the problem of having to implement very long, wide springs for the suspension in a manner capable of oscillation of the mirror and house them on the MEMS chip. Very wide springs (e.g., having a width and thickness between 50 μm and 1500 μm and a length of 500 μm to 10,000 μm) are often required to bring the mirrors to high resonance frequencies and scanning frequencies despite large scanning angles and mirror diameters.

The goal of implementing high scanning frequencies, in conjunction with the requirement to occupy as little chip area as possible, inevitably results in the use of very stiff spring structures. However, particularly in areas where the structure of the suspension has tight radii, high mechanical stresses regularly arise during operation of the mirror due to the deformation of the suspension.

Another problem that occurs with such mirrors designed to combine high scanning frequencies with small dimensions is mechanical crosstalk between the axes, especially with mirrors in which the mirror movement in both axes is achieved by deformation of the same spring structure (“gimballess” design), since the deflection of the mirror in one direction is accompanied by a preload of the suspension, which influences the movement of the mirror in the other axis (and vice versa).

The use of a rigid, solid gimbal (gimbal=cardanic suspension) known from the prior art can at least largely prevent this mechanical crosstalk, since it separates the suspensions of the two axes. However, the high mass of such a gimbal ensures that the scanning axis, which is created by the movement of the gimbal itself, can only implement relatively low scanning frequencies.

It is an object of the invention to provide an improved microscanner which combines high scanning frequencies, large scanning angles, a small design, and mechanically, at least largely, independent axes.

This object is achieved according to the teaching of the independent claim. Various embodiments and refinements of the invention are the subject matter of the dependent claims.

One aspect of the solution presented here relates to a microscanner for projecting electromagnetic radiation onto an observation field. The microscanner has: (i) a deflection element having a mirror surface designed as a micromirror for deflecting an incident electromagnetic beam; (ii) a support structure that surrounds the deflection element at least in some sections, which can in particular be in the form of a frame and in particular can be manufactured from a semiconductor substrate; and (iii) a spring device, by means of which the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations. The spring device has a plurality of spring elements arranged together in a ring around the deflection element, in particular four such spring elements. The spring elements are each anchored on the one hand to a first anchoring point on the support structure and on the other hand (i) indirectly, in particular via a torsion spring (hereinafter also referred to as the “first” torsion spring), or (ii) directly to a second anchoring point on the deflection element. In between (i.e., between the respective first anchoring point and the respective second anchoring point) they each have an at least partially arced course such that this arced course is curved in the direction toward the deflection element (i.e., is convex when viewed from the deflection element).

The term “deflection element” as used here is understood in particular as a body which has a reflective surface (mirror surface) that is smooth enough that reflected electromagnetic radiation, such as visible light, retains its parallelism under the law of reflection and a picture can thus result. The roughness of the mirror surface has to be less than approximately half the wavelength of the electromagnetic radiation for this purpose. The deflection element can in particular be designed as a mirror plate having at least one mirror surface or can include such a mirror plate. In particular, the mirror surface itself can consist of a different material, for example of a metal, which is in particular deposited, than the other body of the deflection element.

The term “oscillation axis” or synonymously “axis” as used herein is to be understood in particular as an axis of rotation of a rotational movement. It is a straight line that defines or describes a rotation or turn.

The term “Lissajous projection” (and variations thereof) as used herein is to be understood in particular as scanning of an observation field with the aid of electromagnetic radiation, which is effectuated by at least two mutually orthogonal oscillations of a deflection device, in particular a single deflection element or a combination of at least two deflection elements, that deflects the radiation into the observation field.

The term “arced course (of a spring element) curved in the direction toward the deflection element” (and variations thereof), as used herein, is to be understood in particular as such a course of the shape of the spring element in which the arc is given by a section of the course lying between two inflection or end points delimiting it, and a straight line orthogonal to a connecting line through the two inflection or end points and through the vertex of the arc extending through the deflection element, extends in particular through its geometric center or center of mass.

As possibly used herein, the terms “comprises,” “contains,” “includes,” “includes,” “has,” “with,” or any other variant thereof are intended to cover non-exclusive inclusion. For example, a method or a device that comprises or has a list of elements is not necessarily restricted to these elements, but may include other elements that are not expressly listed or that are inherent to such a method or such a device.

Furthermore, unless expressly stated to the contrary, “or” refers to an inclusive or and not to an exclusive “or”. For example, a condition A or B is met by one of the following conditions: A is true (or present) and B is false (or absent), A is false (or absent) and B is true (or present), and both A and B are true (or present).

The terms “a” or “an” as used herein, are defined in the meaning of “one or more”. The terms “another” and “a further” and any other variant thereof are to be understood to mean “at least one other”.

The term “plurality” as possibly used herein is to be understood to mean “two or more”.

The term “configured” or “set up” to perform a specific function (and respective modifications thereof), as possibly used herein, is to be understood to mean that the corresponding device or component thereof is already provided in a design or setting in which it can execute the function or that it is at least settable-namely configurable-so that it can execute the function after corresponding setting. The configuration can take place, for example, via a corresponding setting of parameters of a process or of switches or the like for activating or deactivating functionalities or settings. In particular, the device can have multiple predetermined configurations or operating modes, so that the configuration can be carried out by selecting one of these configurations or operating modes.

In a microscanner according to the solution, the axis-dependent mechanical stresses are separated into different areas of the spring device. This results in a decoupling of the two vibration axes, at least to a large extent, in the sense that an interaction (“crosstalk”) between the two oscillation axes is reduced and largely eliminated. In this way, these advantages of a rigid gimbal can be achieved without having to use one. In this way, a particularly compact design of the suspension and thus of the microscanner as a whole can also be achieved in particular.

Due to the special arc shape of the spring devices, their masses are arranged particularly close to the oscillation axes, which makes it possible to achieve a particularly low moment of inertia of the spring device with respect to the two oscillation axes. This in turn promotes or enables high scanning frequencies and scanning angles with a given drive.

In addition, advantages result with regard to the variability of the above-mentioned microscanner design, in particular for the purpose of adaptation to various intended frequency ratios (i.e. ratios of the resonance frequency of the first, in particular “faster”, oscillation axis and the resonance frequency of the second, in particular “slower”, oscillation axis). A certain desired frequency ratio can be achieved relatively easily, depending on the desired use of the microscanner, by an appropriate design during the design phase of the microscanner. The configuration of the resonance frequencies of the two axes and thus of the frequency ratio can be carried out in particular by adjusting the lengths, curvatures of the arc shape, and/or stiffnesses of the spring elements, in particular by means of geometry adjustments.

In particular, exemplary embodiments of such microscanners are possible which for double-resonant Lissajous operation at mirror diameters of circular or ring-shaped micromirrors between 0.5 mm and 30 mm, on the one hand, have large optical scanning angles in the range of at least 20° and, for example, up to 90°, and on the other hand, permit scanning frequencies between 2 kHz and 90 kHz to be achieved and, for cost reasons, do not require more (chip) edge length than approximately twice or three times the mirror diameter. This also opens up wide use in a wide variety of possible applications, for example relating to installing the microscanner in a mobile consumer end product, such as a smartphone, a portable computer, or even a so-called “wearable” device (such as a “Smart Watch”).

Preferred exemplary embodiments of the microscanner are described hereinafter, which in each case, unless expressly excluded or technically impossible, can be combined as desired with one another.

In some embodiments, the spring elements have the same shape as one another and their ring-shaped arrangement with respect to a geometric center of the deflection element has a rotational symmetry. By means of such a symmetrical structure, the complexity of the design of the microscanner is simplified during its design, especially with regard to desired resonance frequencies of the oscillation axes and/or their frequency ratio or frequency difference. In addition, a particularly stable oscillation behavior with a particularly good decoupling of the two oscillation axes can be achieved.

In some embodiments, two of the spring elements are (i) mechanically connected to one another at a point that does not coincide with their first anchoring points or (ii) are formed together in one piece and are anchored jointly to the deflection element indirectly by means of a first torsion spring from a coupling point located between their first anchoring points, in particular centrally therebetween. In case (i), the coupling point can in particular coincide with a connection point at which the two spring elements are mechanically connected to one another.

In this way, the direction and resonance frequency of one of the vibration axes could be determined essentially by the first torsion spring(s). Due to the design-related mass distribution of the torsion springs close to the oscillation axis, particularly low moments of inertia and thus high resonance frequencies (and thus corresponding scanning frequencies in resonant operation) and large scanning angles with respect to this oscillation axis can be achieved. This oscillation axis can therefore in particular be designed as the faster of the two oscillation axes if their resonance frequencies differ.

In addition, when designing the microscanner, the moment of inertia of the oscillation axis determined by the first torsion springs, which in the case of different resonance frequencies of the two oscillation axes can be designed in particular as the slow axis, can be strongly influenced by means of a length adjustment and thus can perform an adjustment of the resonance frequency of the oscillation axis towards a desired frequency ratio of both oscillation axes, more precisely of their resonance frequencies. The length of the first torsion springs is thus largely freely selectable within the scope of the design. This option makes it possible to avoid unfavorable frequency ratios, which could, among other things, result in mechanical crosstalk.

In this way, a high level of resistance with respect to mechanical stress can also be achieved, since the stress is well distributed along the respective course of the spring elements, since smaller radii of curvature, especially at inflection points of the curved course of the spring elements, can be avoided more easily than in the case of their direct anchoring to the deflection element.

In some embodiments, the arced course of at least one, in particular all, of the spring elements is circular or elliptical. This shaping is particularly advantageous with regard to high resistance to mechanical stress, since the stress is well distributed along the respective course of the spring element, since smaller radii of curvature can be avoided. In addition, circular or elliptical arcs have the advantage when designing a microscanner that they are usually easier to simulate than more complex shapes.

In some of these embodiments, the arced course of the spring element spans an angle between 0° and 360°, in particular between 65° and 115°, with respect to a center point of the circular arc or a focal point of the elliptical arc. For reasons of space, angles in the range between 85° and 95°, approximately 90° here, represent a suitable order of magnitude, where there is still sufficient spring length to enable very large deflection angles of the deflection element and thus very large scanning angles, in particular up to 180° or even more.

In some embodiments, at least one of the spring elements, in particular all of them, each has a thickness that is variable along its arced course, in particular with respect to at least one spatial dimension (width and/or thickness), which increases or decreases monotonously, in particular uniformly (i.e., linearly), along the course, at least in the region of the arced course of the respective spring element.

In some embodiments (i) a perpendicular to the mirror surface of the deflection element, when it is in its stable rest position without oscillation relative to the support structure, defines a first direction and (ii) for at least one of the spring elements, its maximum and/or average thickness (“width”) determined along its arced course in a plane orthogonal to the first direction is greater than its maximum or average thickness (“thickness”) along the first direction. In particular, the thickness in a plane orthogonal to the first direction and/or the thickness along the first direction can also be constant. These embodiments offer the advantage that process-related tolerances with respect to the width during structuring are less relevant for wide springs with regard to compliance with the desired spring properties than for narrower springs. The thickness of the spring elements can be determined in particular by a layer thickness or substrate thickness of a semiconductor body (e.g., wafer, for example having a thickness of 80 μm), from which the spring device and optionally also the deflection element and the support structure are formed by means of structuring, in particular by etching. However, in such etching processes, the side wall roughness of the structures produced by etching is often less easy to influence than their surface roughness. In the case of spring elements, the thickness of which is less than their width, the mechanical stress occurring in the spring elements during operation of the microscanner can be easily transferred to the smooth surface, which can be controlled with regard to its exact shape, in particular surface roughness, by which the breaking strength of the spring element(s) can be increased.

In some embodiments, two of the spring elements, the second anchoring points of which (on the deflection element) do not coincide, have a common course section in which the two spring elements are mechanically connected to one another or are formed integrally together. This course section forms a (second) torsion spring, by means of which these two spring elements are jointly suspended on at least one associated first anchoring point on the support structure. Another advantage of this/these second torsion spring(s) is that the choice of their length allows the resonance frequency of the corresponding oscillation axis to be easily adjusted within the framework of the microscanner design.

In some embodiments, the spring device is designed in such a way, in particular with regard to its geometry and/or its material, that the second oscillation axis is defined by the position of the second anchoring points on the deflection element, in particular coincides with a connecting line through the second anchoring points or extends parallel thereto, and has a higher resonance frequency (or equivalent: natural frequency) with regard to its rotational oscillation than the first oscillation axis orthogonal thereto with regard to its rotational oscillation.

In particular, in some of these embodiments, the ratio of the higher to the lower of the resonance frequencies is not an integer, but deviates by at most 10%, preferably by at most 5%, from the ratio of the closest integer value. In such cases, a Lissajous trajectory results in the observation field, or on an object surface (for example projection screen) lying in the observation field transversely to the optical axis of the projection, which can fill or illuminate the image field in a very short time, in particular in the context of a digital image of each pixel of the image field. The time span required for this is largely determined by the choice of resonance frequencies. The nearest integer value can in particular be 1, 2, 3, 4, or 5.

In some embodiments, the microscanner furthermore includes a drive device for directly or indirectly driving the oscillations of the deflection element around the two oscillation axes. In particular, electrostatic, piezoelectric, electromagnetic, and thermal drives come into consideration as drives, which can already be entirely or partially provided and manufactured in the context of MEMS manufacturing at wafer level. In addition, so-called external drives are also possible, which supply the component with vibration energy in the appropriate frequency range from an external non-MEMS actuator, such that the MEMS mirror begins to oscillate in one or both axes.

In particular, the drive device according to some of these embodiments can include at least one drive element having a piezo actuator which is arranged on one of the spring elements in order to set it into oscillation. This represents a particularly space-saving and moreover, due to the direct coupling of the piezo actuator with the spring element, particularly effective and, in particular, energy-efficient possibility for implementing a drive device for the microscanner.

In some embodiments, the drive device is configured so that it can set the deflection element into a double-resonant oscillation with respect to the first and second oscillation axes. For this purpose, the actuator system can in particular include or consist of one or more actuators. This enables particularly low-energy operation of the microscanner as well as large scanning angles and, depending on the choice of resonance frequencies, also high scanning frequencies.

In some of these embodiments, the drive device is configured in such a way that it can set the deflection element into a double-resonant oscillation with respect to the first and second oscillation axes in such a way that for the frequency ratio of the resonance frequency f₁ with respect to the faster of the two oscillation axes to the resonance frequency f₂ with respect to the slower of the two oscillation axes, the following applies: f₁/f₂=F+v, wherein F is a natural number and the following applies to the detuning v: v=(f₁−f₂)/f₂ with (f₁−f₂)<200 Hz, wherein v is not an integer. This results here in a frequency ratio f₁/f₂ close to 1, 2, 3, or 4, etc.

The detuning v can in particular be achieved in such a way that only one of the two oscillation frequencies or both differ or differ from the respective resonance frequency for the associated oscillation axis. The detuning v in relation to an integer frequency ratio plays a major role here, because this detuning of the frequency determines how quickly the Lissajous trajectory continues to move spatially. With an integer ratio, the detuning is zero and the trajectory is stationary and constantly reproduces itself in this form.

At a noninteger detuning v>0, in contrast, the trajectory begins to travel, specifically within a certain interval the faster the greater the detuning v is in relation to the integer ratio. The speed of progress at which the trajectory continues to move can advantageously be chosen so that a specific trajectory repetition rate (complete phase passages/time), for example from the frequency range 30 Hz to 100 Hz is established, with which the trajectory reproduces or reproduces under ideal undisturbed conditions. (For explanation: Exact reproduction is often not possible, especially when using phase-locked loops or other control loops. Nevertheless, the advantages of a well-chosen detuning and an accompanying favorable speed of progress of the trajectory remain). On the basis of a detuning v selected in this way, in particular an improved, i.e., increased line density, at least on average over time, can also be achieved.

In some embodiments, at least two of the following functional elements of the microscanner are at least partially manufactured from the same plate-shaped substrate: the spring device, the deflection element, the support structure. In particular, the substrate can be a semiconductor substrate, such as a silicon substrate, from which at least two, preferably all, of the aforementioned functional elements are manufactured. On the one hand, this has the advantage that the microscanner, or the functional elements mentioned thereof, can be produced within the scope of the same substrate processing, instead of being initially produced as separate components in separate processes and subsequently assembled to form microscanners. On the other hand, in particular the production of the microscanner or the functional elements mentioned from a single substrate allows a particularly space-efficient or surface-efficient solution, since here production processes known from semiconductor or microsystem technology can be used, which in particular allow the deliberate production of ultrasmall structures.

Further advantages, features, and possible applications of the present invention result from the following detailed description in conjunction with the figures.

In the figures:

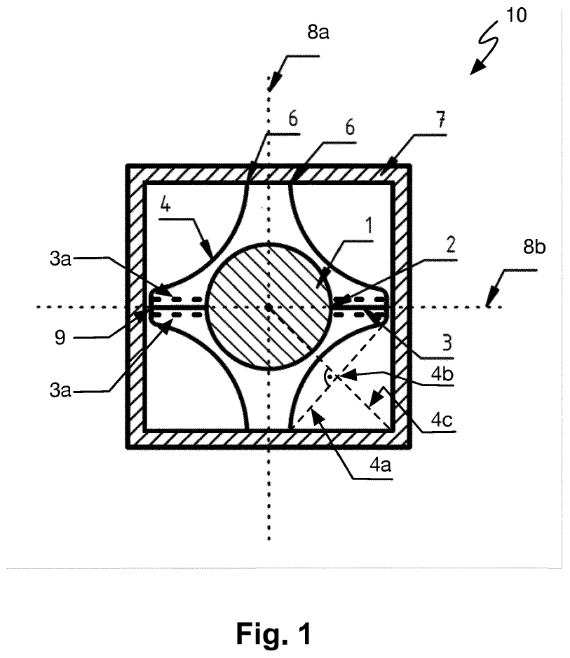

FIG. 1 schematically shows a first embodiment of a biaxial microscanner having a spring device having four spring elements and two torsion springs anchored to the deflection element;

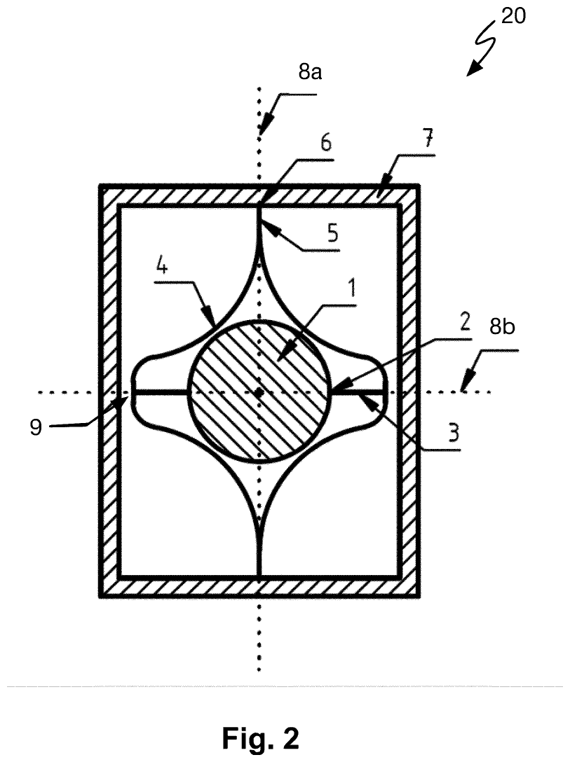

FIG. 2 schematically shows a second embodiment of a biaxial microscanner with a spring device having four spring elements and two (further) torsion springs anchored to the support structure;

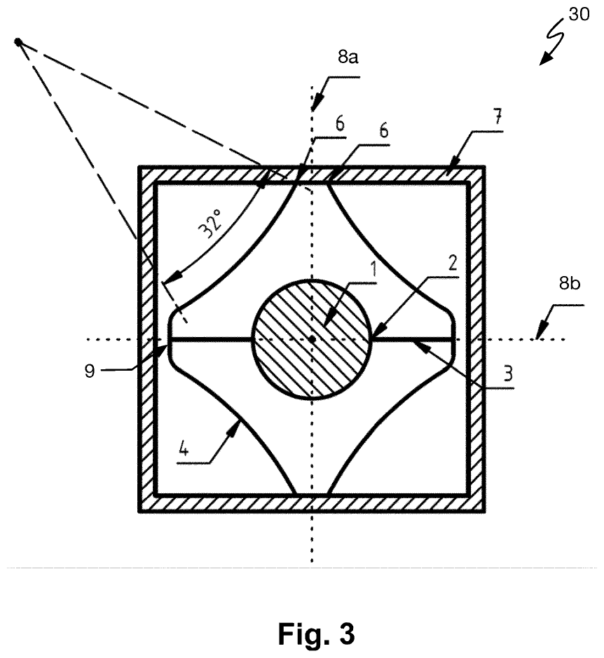

FIG. 3 schematically shows a third embodiment of a biaxial microscanner, in which the arced sections of the spring elements each enclose an acute angle of less than 90°, in particular of 32°; and

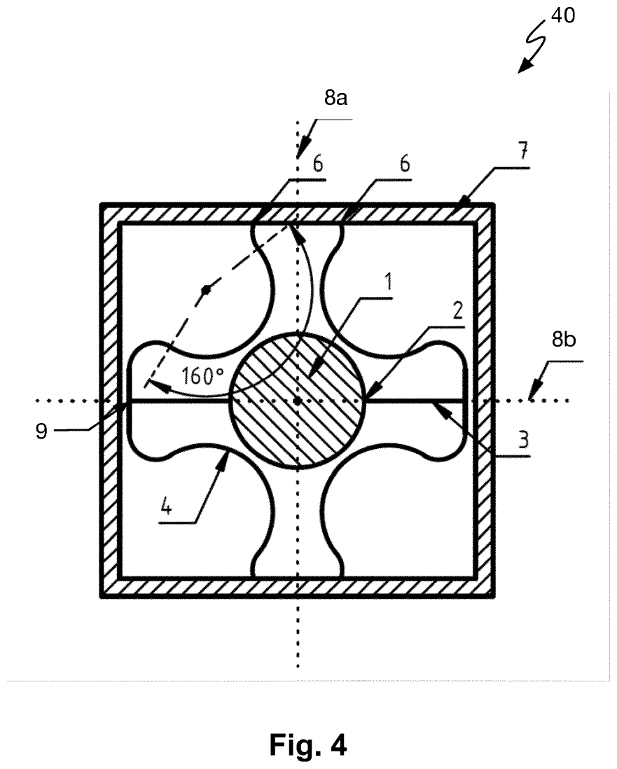

FIG. 4 schematically shows a third embodiment of a biaxial microscanner, in which the arced sections of the spring elements each enclose an angle of greater than 90°, in particular of 160°.

In the figures, the same reference numerals denote the same, similar or corresponding elements. Elements depicted in the figures are not necessarily represented to scale. Rather, the various elements shown in the figures are presented in such a way that their function and general purpose can be understood by those skilled in the art. Connections and couplings, shown in the figures, between functional units and elements can also be implemented as an indirect connection or coupling, unless expressly stated otherwise.

Functional units can be implemented in particular as hardware, software or a combination of hardware and software.

FIG. 1 schematically shows a biaxial microscanner 10 according to a first embodiment of the present solution. The microscanner 10 is manufactured as a MEMS from a plate-shaped substrate, in particular a semiconductor substrate such as a silicon substrate, in particular by structuring the substrate, typically with the aid of lithography and etching processes.

The microscanner 10 has a deflection element 1 in the form of a mirror plate, which is suspended in a manner capable of oscillation by means of a spring device, which has four spring elements 4 arranged as a whole in a ring around the deflection element, on a frame-shaped planar support structure 7 surrounding the deflection element 1 on all sides around two mutually orthogonal oscillation axes 8a and 8b. The spring elements 4 each have an arced course that is curved, at least in sections, towards the deflection element 1 and are each individually anchored with one of their ends to a respective first anchoring point 6 on the support structure 7. The arc shape can in particular be circular or elliptical.

The course of the shape of each spring element 4 is selected such that its respective arc is given by a section of the course lying between two inflection or end points that delimit it (wherein, in the microscanner 10, each arc is given by an end point of the respective spring element 4 at its anchoring point 6 on the chip frame and by an inflection point on the other side of the arc), and a straight line 4c (or a perpendicular projection thereof onto the plane defined by the chip frame 7) that is orthogonal to a connecting straight line 4a extending through the two inflection points and through the vertex 4b of the arc and extends through the deflection element 1, in particular through its geometric center or its center of mass.

The width of the spring elements (in the plane defined by the chip frame 7), in particular the width of their arced sections, can in particular be chosen to be larger than their thickness (measured orthogonally to the plane defined by the chip frame 7). Overall, the ring-shaped arrangement of the spring elements 4 has a rotational symmetry, especially a four-fold symmetry, with respect to a geometric center point of the deflection element 1 (which is circular here, for example).

The support structure 7, which can also be referred to as a chip frame, has a high rigidity, so that it essentially acts as a rigid structure for anchoring the spring device during oscillating movements of the deflection element 1. In particular, it can have a rectangular shape. In particular, in the case of rotational symmetry (e.g., four-fold rotational symmetry), it can especially be square, as shown in FIG. 1.

Each of the spring elements 4 is connected at its other end to an associated second spring element 4 at a coupling point 9, so that the microscanner 10 has a total of two separate spring structures, each having two spring elements 4 (in FIG. 1, the two spring elements to the left of axis 8a together form a first spring structure and the two spring elements to the right of axis 8a form a second spring structure). The suspension of the deflection element 1 is achieved in each of the two spring structures by means of a respective torsion spring 3 which extends between the respective coupling point 9 and the deflection element 1, to which it is anchored at a respective second anchoring point 2. The respective two spring elements 4 and the respective torsion spring 9 of each of the spring structures can in particular also be formed integrally, i.e., together in one piece. This can be due in particular to appropriate structuring of a common substrate from which the microscanner 10 is manufactured. In addition, the deflection element 1 and/or the support structure 7 can also be formed integrally with the spring structures, in particular such that the structure of the microscanner 10 shown in FIG. 1 is then integral as a whole.

On the one hand, the deflection element 1 can oscillate rotationally around a first oscillation axis 8a, wherein in addition to the deflection element 1, the two spring structures and the two torsion springs 3 are also deflected relative to the plane defined by the chip frame 7. The spring force for this first oscillation is mainly caused by a deformation of the spring elements 4, in particular of their sections close to the frame.

On the other hand, the deflection element 1 can also oscillate rotationally around the second oscillation axis 8b, wherein above all the deflection element 1 is deflected relative to the plane defined by the chip frame 7 and above all the two torsion springs 9 and the adjoining sections of the spring elements 4 provide the spring force required for this second oscillation. The microscanner 10 can in particular be designed such that the oscillation axis 8a is slower than the oscillation axis 8b, i.e., that it has a lower resonance frequency than the latter. The design of the microscanner 10 favors such an assignment of fast and slow axes in particular in that the torsion springs 9, which oscillate significantly next to the deflection element 1, are located essentially on or very close to the oscillation axis 8b and therefore have a very low moment of inertia. In contrast, during an oscillation around the oscillation axis 8a, the entire spring structures oscillate, some of which are located relatively far away from the oscillation axis 8a and thus have a larger moment of inertia with respect to this axis 8a. However, in order to enable high vibration frequencies and thus scanning frequencies in absolute terms even with this slower vibration axis, the spring elements 4 have the above-mentioned arced sections curved towards the deflection element 1. This ensures that the largest possible part of the mass of the spring elements 4 is shifted in the direction of the oscillation axis 8a and thus the overall moment of inertia is reduced.

The suspension of the deflection element 1 provided by the spring device, i.e., the two spring structures, acts like a gimbal (cardanic suspension) in that the mechanical crosstalk between the two oscillations or oscillation axes 8A and 8b is minimized by separating the axis-dependent mechanical stresses so that they occur, at least largely, in different sections of the spring elements 4. This type of suspension of the deflection element 1 with extensive decoupling of the axes acts as a spring and therefore differs fundamentally from known suspensions by means of a gimbal, which is in particular rigid.

In one possible variant of the microscanner 10, the spring elements 7 are each individually anchored to the deflection element 1. Instead of a single torsion spring 9 per spring structure, the sections 3a of the spring elements 4 anchored directly to the deflection element 1 and shown by dashed lines in FIG. 1 each form a torsion spring. This variant can in particular also be applied to the embodiments shown below in FIGS. 2 to 4.

For its drive, the microscanner 10 can in particular have one or more piezo elements (not shown in the figures for the sake of clarity). They can in particular be arranged on one or more, in particular all, of the spring elements 4 in order to deform them in a targeted manner when appropriately actuated and thus to provide them with energy to drive the oscillations. In order to achieve the lowest possible impact on the moment of inertia of the spring elements 4 with respect to the oscillation axes, the piezo elements can be arranged in particular on the arced sections of the spring elements 4 where they have the greatest proximity to the center, center of mass, or edge of the deflection element 1, i.e., in the case of a circular deflection element 1 where the arced section comes closest to the deflection element 1 (cf. tip of the arrow to reference numeral 4).

The described type of suspension results in two mutually perpendicular oscillation axes 8a and 8b, around which the deflection element 1 can oscillate resonantly in both axes. This operating mode can be used particularly advantageously in laser projection displays and imaging sensors such as 3D cameras, LIDAR sensors (LIDAR=Light detection and ranging or Light imaging, detection, and ranging), OCT devices (OCT=optical coherence tomography), etc., as well as in laser material processing.

FIG. 2 schematically shows a biaxial microscanner 20 according to a second embodiment of the present solution. The microscanner 20 is largely identical to the microscanner 10, so that only the significant differences will be discussed below and otherwise what has been said about FIG. 1 or the microscanner 10 also applies to the microscanner 20. The same applies with regard to FIGS. 3 and 4.

A significant difference between embodiments 10 and 20 is that in the microscanner 20, on each relevant side of the chip frame 7 (i.e., top and bottom in FIG. 2), the spring structures or their spring elements 4 are no longer anchored individually, but jointly via a common spring section 5, which forms a (second) torsion spring, to the chip frame 7 at a respective (first) anchoring point. As can be seen from FIG. 2, the two upper ends of the two spring structures in FIG. 2, i.e., the two spring elements 4 located above the oscillation axis 8b, are connected to one another or are integrally embodied in the section 5 forming a (second) torsion spring and are anchored together to the chip frame 7. The same applies correspondingly to the two spring elements 4 located below the oscillation axis 8b.

This embodiment 20 can in particular promote a further minimization of the mechanical stress in the spring elements 4 and consequently an increased robustness and service life of the microscanner. The risk that the microscanner, in particular its delicate spring elements 4, will come close to its breaking point when operated at high frequencies and/or large deflections can thus be effectively counteracted. Viewed the other way around, it permits. Such a design of a microscanner embodies the spring structures as correspondingly more delicate and thus with lower mass, which in turn is advantageous with regard to high operating frequencies and large deflection angles.

With such a design, the spring characteristic curves of the torsion springs 5 can also be assumed to be linear over a wide range, which facilitates actuation of the microscanner for its operation, since less complex controllers can be used.

A further change in relation to the design of the microscanner 10 from FIG. 1 can optionally consist of adapting the shape of the support structure or the chip frame 7, in particular by selecting a rectangular shape deviating from a square. This is particularly advantageous with regard to a suitable selection of the length of the second torsion spring 5 with regard to a tuning of the resonance frequency, in particular of the oscillation axis 8a.

FIG. 3 schematically illustrates a biaxial microscanner 30 according to a third embodiment of the present solution, which corresponds to a special design of the microscanner 10 from FIG. 1, but is correspondingly also applicable to the microscanner 20 from FIG. 2.

It is characterized in particular by the fact that the arced sections of the spring elements 4 each enclose an acute angle Φ<90°, in particular, for example, 32°. Such variants are characterized in particular in that strong curvatures can be largely avoided in the course of the spring elements 4, which is advantageous with regard to a high breaking limit and thus a high level of robustness and service life.

FIG. 4 schematically illustrates a biaxial microscanner 40 according to a still another, fourth embodiment of the present solution, which again corresponds to a special design of the microscanner 10 from FIG. 1, but is correspondingly also applicable to the microscanner 20 from FIG. 2.

It is characterized in particular by the fact that the arced sections of the spring elements 4 each enclose an obtuse angle Φ>90°, in particular, for example, 160°. Such variants are characterized in particular in that the strongly pronounced arced course of the spring elements 4 promotes a mass distribution in which the mass of the spring elements is particularly close to the oscillation axis 8a. Consequently, high resonance frequencies with respect to this oscillation axis can be achieved particularly well here.

For reasons of space, angles Φ in the range of 85° to 95°, in particular Φ≈90°, represent a suitable order of magnitude here, in which there is still sufficient spring length to enable large deflection angles.

Unless otherwise stated, the following explanations are independent of a specific embodiment of a microscanner according to the solution and are therefore in particular applicable to all embodiments 10 to 40 from FIGS. 1 to 4 and their mentioned variants, to which reference is also made below for the purpose of explanation.

Particularly advantageous, especially for a biaxially resonant Lissajous operation, are microscanners having two fast axes, in which the resonance frequency f₁ for the faster of the axes and f₂ for the slower of the axes nearly but not exactly form an integer ratio to one another. So: f₁/f₂=1, 2, 3, 4, 5 etc., because in this case a Lissajous trajectory is always formed, which can advantageously efficiently fill the image field in a very short time, which is adjustable itself by selecting the resonance frequencies.

A microscanner according to the solution can be easily adapted to different frequency ratios during its design. For example, for a certain frequency ratio, a difference frequency of the two oscillation axes 8a and 8b can be set so that this difference corresponds to the desired refresh rate independently of the integer ratio. For example, for a frequency ratio f₁/f₂≈2, the slower first axis 8a can be tuned to 10 KHz and the faster second axis 8b to 20.2 kHz in order to implement a refresh rate of 200 Hz. Likewise, for example, a frequency ratio f₁/f₂≈3 could be implemented by tuning the axes to f₁=5 kHz and f₂=15.2 KHz. For a frequency ratio f₁/f₂≈4, for example, the axes would be designed for f₁=5 kHz and f₂=20.2 kHz (etc.).

The adjustment of the resonance frequencies to the two vibration axes 8a and 8b, in particular their ratio and, if applicable, detuning in relation to an integer ratio, can be achieved in particular by (if available in the respective microscanner design):
the length of the (first) torsion springs 3 (or 3a) on the deflection element 1 and thus the moment of inertia acting on the axis 8a transverse thereto is adjusted.
the width of the (first) torsion springs 3 (or 3a) on the deflection element 1 and thus their stiffness is adjusted (the same applies, if necessary, to the second torsion spring 5 for suspension on the support structure 7).
the width of the spring elements 4, in particular of their arced sections, and thus their stiffness is varied.
the thickness and thus the stiffness of the spring elements 4 is varied.
if necessary, the geometry of a support structure on the side of the deflection element 1 opposite to the mirror surface and thus its moment of inertia is adapted.

Electrostatic, piezoelectric, electromagnetic, and thermal drives come into consideration as drives, which are in particular already entirely or partially provided and manufactured in the context of MEMS manufacturing at wafer level. In addition, so-called external drives are also possible, which supply the microscanner with vibration energy in the appropriate frequency range from an external non-MEMS actuator, such that the deflection element 1 begins to oscillate in one or both oscillation axes 8a and/or 8b. As already mentioned, piezoelectric actuators can be arranged particularly advantageously on the spring elements themselves, where they can excite the vibration of the deflection element 1 particularly (energy) efficiently.

While at least one exemplary embodiment has been described above, it is to be noted that a large number of variations thereto exist. It is also to be noted that the exemplary embodiments described only represent non-limiting examples, and are not intended to restrict the scope, the applicability, or the configuration of the devices and methods described herein. Rather, the preceding description will provide those skilled in the art with guidance for implementing at least one exemplary embodiment, wherein it is apparent that various changes in the operation and arrangement of elements described in an exemplary embodiment may be made without departing from the scope of the subject matter defined in the appended claims and its legal equivalents.

### LIST OF REFERENCE NUMERALS

1 deflection element, in particular mirror plate
2 second anchoring point, on mirror plate
3 (first) torsion spring anchored to mirror plate
3a section of a spring element 4 anchored directly from the deflection element
4 spring element with arced section
4a straight line through the inflection points or end points delimiting the arc
4b vertex of the arc
4c straight line through the vertex 4b and orthogonal to straight line 4a
5 (second) torsion spring, anchored to the support structure (chip frame)
6 first anchoring point(s), on the support structure (chip frame)
7 support structure, in particular rigid chip frame
8a first (in particular slower) oscillation axis
8b second (in paticular faster) oscillation axis
9 coupling point
10 first embodiment of a biaxial microscanner
20 second embodiment of a biaxial microscanner
30 third embodiment of a biaxial microscanner
40 fourth embodiment of a biaxial microscanner
Φ angle spanned by arced section of a spring element

What is claimed is:

1. A microscanner for projecting electromagnetic radiation onto an observation field, wherein the microscanner comprises:
a deflection element having a mirror surface designed as a micromirror for deflecting an incident electromagnetic beam;
a support structure surrounding the deflection element at least in some sections; and
a spring device, by means of which the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations;
wherein the spring device has a plurality of spring elements arranged together in a ring around the deflection element, which are each anchored, on the one hand, to a first anchoring point on the support structure and, on the other hand, are anchored directly or indirectly to a second anchoring point on the deflection element and have an at least partially arced course therebetween such that this arced course is curved in the direction toward the deflection element.

2. The microscanner according to claim 1, wherein the spring elements have the same shape as one another and their ring-shaped arrangement has a rotational symmetry with respect to a geometric center point of the deflection element.

3. The microscanner according to claim 1, wherein two of the spring elements are mechanically connected to one another at a point that does not coincide with their first anchoring points or are integrally formed together and are anchored jointly to the deflection element indirectly by means of a first torsion spring from a coupling point lying between their first anchoring points.

4. The microscanner according to claim 1, wherein the arced course of at least one of the spring elements is circularly arced or elliptically arced.

5. The microscanner according to claim 4, wherein the arced course of the spring element spans an angle between 0° and 360° with respect to a center point of the circular arc or a focal point of the elliptical arc.

6. The microscanner according to claim 1, wherein at least one of the spring elements has a thickness which is variable along its arced course and which increases or decreases monotonously along the course at least in the area of the arced course of the respective spring element.

7. The microscanner according to claim 1, wherein:
a perpendicular to the mirror surface of the deflection element, when the latter is in its stable rest position relative to the support structure without oscillation, defines a first direction; and
in at least one of the spring elements, the maximum and/or average thickness determined along its arced course in a plane orthogonal to the first direction is greater than its maximum or average thickness along the first direction.

8. The microscanner according to claim 1, wherein each two of the spring elements, the second anchoring points of which do not coincide, have a common section in which the two spring elements are mechanically connected to one another or are integrally formed together, wherein this section forms a second torsion spring by means of which these two spring elements are jointly suspended from at least one associated first anchoring point on the support structure.

9. The microscanner according to claim 1, wherein the spring device is designed such that the second oscillation axis is defined by the position of the second anchoring points on the deflection element and has a higher resonance frequency with respect to its rotary oscillation than the orthogonal first oscillation axis with respect to its rotary oscillation.

10. The microscanner according to claim 9, wherein the ratio of the higher to the lower of the resonance frequencies is not an integer but deviates by at most 10%, preferably at most 5%, from the integer value closest to the ratio.

11. The microscanner according to claim 10, wherein the nearest integer value is 1, 2, 3, 4, or 5.

12. The microscanner according to claim 1, furthermore including a drive device for directly or indirectly driving the oscillations of the deflection element around the two oscillation axes.

13. The microscanner according to claim 12, wherein the drive device includes at least one drive element having a piezo actuator which is arranged on one of the spring elements in order to cause it to oscillate.

14. The microscanner according to claim 12, wherein the drive device is configured so that it can set the deflection element into a double-resonant oscillation with respect to the first and second oscillation axes.

15. The microscanner according to claim 14, wherein the drive device is configured in such a way that it can cause the deflection element undergo double-resonant oscillation with respect to the first and second oscillation axes in such a way that the following applies to the frequency ratio of the resonance frequency f₁ with respect to the faster of the two oscillation axes to the resonance frequency f₂ with respect to the slower of the two oscillation axes: f₁/f₂=F+v, wherein F is a natural number and the following applies to the detuning v: v=(f₁−f₂)/f₂ with (f₁−f₂)<200 Hz, wherein v is not an integer.

16. The microscanner according to claim 1, wherein at least two of the following functional elements of the microscanner are at least partially manufactured from the same plate-shaped substrate: the spring device, the deflection element, the support structure.

17. The microscanner according to claim 2, wherein two of the spring elements are mechanically connected to one another at a point that does not coincide with their first anchoring points or are integrally formed together and are anchored jointly to the deflection element indirectly by means of a first torsion spring from a coupling point lying between their first anchoring points.

18. The microscanner according to claim 3, wherein the arced course of at least one of the spring elements is circularly arced or elliptically arced.

18. The microscanner according to claim 5, wherein the arced course of at least one of the spring elements is circularly arced or elliptically arced.

19. The microscanner according to claim 6, wherein:
a perpendicular to the mirror surface of the deflection element, when the latter is in its stable rest position relative to the support structure without oscillation, defines a first direction; and
in at least one of the spring elements, the maximum and/or average thickness determined along its arced course in a plane orthogonal to the first direction is greater than its maximum or average thickness along the first direction.

20. The microscanner according to claim 7, wherein each two of the spring elements, the second anchoring points of which do not coincide, have a common section in which the two spring elements are mechanically connected to one another or are integrally formed together, wherein this section forms a second torsion spring by means of which these two spring elements are jointly suspended from at least one associated first anchoring point on the support structure.
